(19) United States
(12) Patent Application Publication
(10) Pub. No.: US 2026/0100597 A1
(43) Pub. Date: Apr. 9, 2026

(54) POWER CONVERTER AND POWER CONVERSION SYSTEM

(71) Applicants: DENSO CORPORATION, Kariya-city (JP); TOYOTA JIDOSHA KABUSHIKI KAISHA, Toyota-shi (JP)

(72) Inventors: Junya MATSUSHITA, Kariya-city (JP); Yohei IMAI, Kariya-city (JP); Nobutaka TANAKA, Nagoya-city (JP); Kotaro ASABA, Nagoya-city (JP)

(73) Assignees: DENSO CORPORATION, Kariya-city (JP); TOYOTA JIDOSHA KABUSHIKI KAISHA, Toyota-shi (JP)

(21) Appl. No.: 19/416,409

(22) Filed: Dec. 11, 2025

Related U.S. Application Data
(63) Continuation of application No. PCT/JP2024/022492, filed on Jun. 21, 2024.

(30) Foreign Application Priority Data
Jul. 11, 2023 (JP) 2023-114031

(51) Int. Cl. H02J 7/60; G01R 15/20; G01R 19/00; H02M 7/483; H02M 7/537

(52) U.S. Cl. CPC H02J 7/60; G01R 15/202; G01R 19/0092; H02M 7/483; H02M 7/537

(57) ABSTRACT

A power converter is connected to an external device and a power supply, and includes a transformer circuit, connection terminal, two transformer current paths, a bypass current path, and a sensor device. The connection terminal interfaces with the external device. The two transformer current paths are positioned at the high-and low-potential sides and connect to the terminal and power supply via the transformer circuit. The bypass current path branches from one transformer current path, bypassing the transformer circuit, and establish or interrupt the electrical connection between the terminal and power supply. The sensor device is at the first and second current paths, where the first current path includes a branching node connected to the bypass path and terminal, and the second current path does not. The sensor device outputs a signal that varies based on the first and second currents, which flow through the respective paths and transformer circuit.

### CROSS REFERENCE TO RELATED APPLICATIONS

The present application is a continuation application of International Patent Application No. PCT/JP2024/022492 filed on Jun. 21, 2024, which designated the U.S. and claims the benefit of priority from Japanese Patent Application No. 2023-114031 filed on Jul. 11, 2023. The entire disclosures of all of the above applications are incorporated herein by reference.

### TECHNICAL FIELD

The present disclosure relates to a power converter and a power conversion system.

### BACKGROUND

A power converter may be a motor drive system. The motor drive system may include a battery and an inverter that converts the DC power stored in the battery into three-phase AC power and supplies the converted power to a motor. In addition, the motor drive system is connectable to a charging facility. The motor drive system may selectively use a first charging mode, in which external charging power is supplied directly to the battery, and a second charging mode, in which external charging power is supplied to the neutral point of the motor and then boosted by controlling the switching elements of the inverter before being supplied to the battery.

### SUMMARY

According to an aspect of the present disclosure, a power converter is configured to be connected to an external device and a power supply. The power converter includes a transformer circuit, a connection terminal, two transformer current paths, a bypass current path, and a sensor device. The connection terminal is an electrical port configured to be connected to the external device. Two transformer current paths are respectively located at a high-potential side and a low-potential side of the power converter. The two transformer current paths are electrically connected to the connection terminal and the power supply via the transformer circuit. The bypass current path is a current path that branches from one of the two transformer current paths and bypasses the transformer circuit. The bypass current path is configured to selectively establish and interrupt an electrical connection between the connection terminal and the power supply. The sensor device may be located at a first current path and a second current path. The first current path is the one of the two transformer current paths and has a branching node to which the bypass current path is connected. The branching node is located between the transformer circuit and the connection terminal. The second current path is another of the two transformer current paths. The second current path does not have the branching node. The sensor device may output an electrical signal that varies according to a first current and a second current. The first current flows between the branching node of the first current path and the transformer circuit, and the second current flows through the second current path.

### BRIEF DESCRIPTION OF DRAWINGS

FIG. 1 is a circuit diagram showing a schematic configuration of a power conversion system.

FIG. 2 is a plan view showing a schematic configuration of a sensor device.

FIG. 3 is a cross-sectional view taken along line III-III of FIG. 2.

FIG. 4 is a flowchart illustrating an energization process of an ECU.

FIG. 5 is a flowchart illustrating a determination process of the ECU.

FIG. 6 is a circuit diagram showing a schematic configuration of a power conversion system according to a modified example.

### DETAILED DESCRIPTION

In a motor drive system, an abnormality may occur in a current path. In addition, in the motor drive system, if an abnormality occurs in the current path, a fault may occur in the charging facility.

According to a first aspect of the present disclosure, a power converter is connected to an external device and a power supply. The power converter includes a transformer circuit, a connection terminal, two transformer current paths, a bypass current path, and a sensor device. The connection terminal is an electrical port to be connected to the external device. Two transformer current paths are respectively located at a high-potential side and a low-potential side of the power converter. The two transformer current paths are electrically connected to the connection terminal and the power supply via the transformer circuit. The bypass current path is a current path that branches from one of the two transformer current paths and bypasses the transformer circuit. The bypass current path selectively establishes and interrupts an electrical connection between the connection terminal and the power supply. The sensor device is located at a first current path and a second current path. The first current path is the one of the two transformer current paths and has a branching node to which the bypass current path is connected. The branching node is located between the connection terminal and the transformer circuit. The second current path is another of the two transformer current paths. The second current path does not have the branching node. The sensor device outputs an electrical signal that varies according to a first current and a second current. The first current flows between the branching node of the first current path and the transformer circuit, and the second current flows through the second current path.

In the power converter as described above, the first current and the second current change depending on whether the transformer current paths and the bypass current path are normal, or whether an abnormality has occurred in either the transformer current paths or the bypass current path. Therefore, the electrical signals from the sensor device differ between normal and abnormal conditions. Accordingly, the power converter can detect whether an abnormality has occurred in the transformer current path or the bypass current path.

According to a second aspect of the present disclosure, a power conversion system is connected to an external device and a power supply. The power conversion system includes a transformer circuit, a controller, a connection terminal, two transformer current paths, a bypass current path, and a sensor device. The controller controls the transformer circuit. The connection terminal is an electrical port to be connected to the external device. Two transformer current paths are respectively located at a high-potential side and a low-potential side of the power conversion system. The two transformer current paths are electrically connected to the connection terminal and the power supply via the transformer circuit. The bypass current path is a current path that branches from one of the two transformer current paths and bypasses the transformer circuit. The bypass current path selectively establishes and interrupts an electrical connection between the connection terminal and the power supply. The sensor device is located at a first current path and a second current path. The first current path is the one of the two transformer current paths and has a branching node to which the bypass current path is connected. The branching node is located between the connection terminal and the transformer circuit. The second current path is another of the two transformer current paths. The second current path does not have the branching node. The sensor device outputs an electrical signal that varies according to a first current and a second current. The first current flows between the branching node of the first current path and the transformer circuit, and the second current flows through the second current path. The controller executes a voltage transformation operation of the transformer circuit, and determines, during execution of the voltage transformation operation, respective directions of the first current and the second current that are indicated by the electrical signal.

In the power conversion system as described above, the first current and the second current differ depending on whether the transformer current path and the bypass current path are normal, or whether an abnormality has occurred in either the transformer current path or the bypass current path. Therefore, the controller determines the directions of the first current and the second current indicated by the electrical signals during execution of the voltage transformation operation. Accordingly, the controller can detect, based on the electrical signals, whether an abnormality has occurred in the transformer current path or the bypass current path. In this manner, the power conversion system can detect abnormalities in the current paths.

### Embodiment

Hereinafter, various embodiments for carrying out the present disclosure will be described with reference to the drawings. In each embodiment, the same reference numerals are assigned to parts corresponding to those described in preceding embodiments, and duplicate explanations may be omitted. In each embodiment, when only a part of the configuration is described, the other portions of the configuration may be referred to and applied from other embodiments previously described.

### Power Conversion System

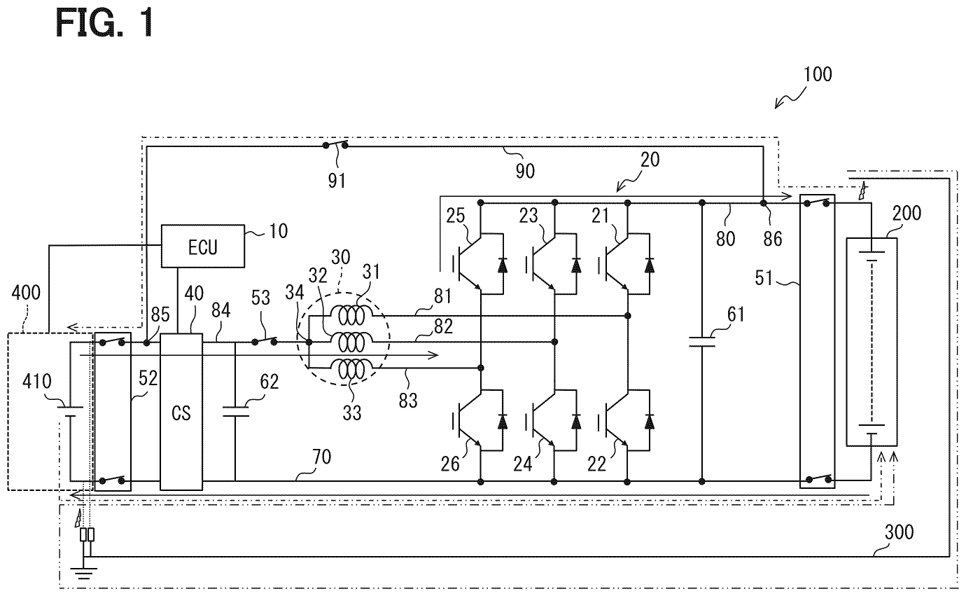

A power conversion system 100 will be described with reference to FIG. 1. FIG. 1 illustrates the power conversion system 100 in a state where a charging stand 400 is connected. The charging stand 400 corresponds to a charging device or a charger.

The power conversion system 100 is configured so as to be mountable, for example, on a moving body. Examples of the moving body include automobiles, trains, and aircraft. In the present embodiment, an automobile is used as an example of the moving body. In the present embodiment, as examples of automobiles, electric vehicles or hybrid vehicles equipped with a rechargeable battery 200 are adopted. The automobile is equipped with, for example, the power conversion system 100, a battery 200, and a chassis 300. The battery 200 corresponds to a power source or a power supply.

The power conversion system 100 includes a power converter and an ECU 10. The power converter may also be referred to as a power conversion device. The power converter includes, for example, an inverter circuit 20, a motor device 30, a sensor device 40, relays 51 to 53, capacitors 61 and 62, and wiring groups. The power converter may also be provided with components such as an EMC filter.

Furthermore, the power conversion system 100 is electrically connectable to the battery 200 and the charging stand 400 (a charging power source 410). The power conversion system 100 operates in a driving mode for driving the motor device 30, and in a charging mode for charging the battery 200 when connected to the charging stand 400. The state in which the charging stand 400 is connected may also be referred to as an external connection mode. Naturally, in the driving mode, the power conversion system 100 is not connected to the charging stand 400. The battery 200, together with the power converter, is adapted to the vehicle. On the other hand, the charging stand 400 is provided outside the vehicle. Therefore, the charging stand 400 may also be referred to as an external device. The charging power source 410 may also be referred to as a charging power supply.

The battery 200 serves as the power source for the vehicle. The battery 200 may adopt, for example, a lithium-ion battery. In other words, the battery 200 is capable of being repeatedly charged and discharged. The battery 200 may also be referred to as a storage battery, rechargeable battery, or simply as a battery. The battery 200 corresponds to a power source or a power supply.

The charging stand 400 is a charging facility for recharging the battery 200. The charging stand 400 is equipped with a charging power source 410. The charging stand 400 may also be equipped with, for example, a charging cable and a computer. The charging cable is electrically connected to the charging power source 410. The charging cable is attachable to and detachable from an external connection relay 52. The charging power source 410 is electrically connected to the power conversion system 100 when the charging cable is attached to the external connection relay 52. The charging stand 400 corresponds to an external device.

The ECU 10 is equipped with a processing unit such as a CPU, a memory device including RAM and ROM, and input/output devices. The input/output device is electrically connected to, for example, each of switching elements 21 to 26 of the inverter circuit 20, the relays 51 to 53 and 91, and the sensor device 40.

The processing unit executes programs stored in the memory device. The processing unit performs computational processing in accordance with the program. The computational processing may also be referred to as calculation processing. In addition, the processing unit performs computational processing while utilizing data stored in the memory device and sensor signals from the sensor device 40. Then, the processing unit controls each of the switching elements 21 to 26, the relays 51 to 53, and the bypass relay 91 via the input/output device. Furthermore, the processing unit is electrically connectable to the charging stand 400 via the input/output device. In the following, the processing operations performed by the processing unit will be described as the processing operations of the ECU 10.

The processing operations of the ECU 10 will be described in detail later. The ECU 10 corresponds to a control device, a control unit, or a controller. The sensor signal corresponds to an electrical signal.

The inverter circuit 20 includes, as switching elements, a U-phase upper arm switch 21, a U-phase lower arm switch 22, a V-phase upper arm switch 23, a V-phase lower arm switch 24, a W-phase upper arm switch 25, and a W-phase lower arm switch 26. The motor device 30 includes a U-phase coil 31, a V-phase coil 32, a W-phase coil 33, and a neutral point 34. Here, a three-phase motor is adopted as an example of the motor device 30. However, the present disclosure is not limited this example.

The U-phase upper arm switch 21 and the U-phase lower arm switch 22 are connected in series between a negative-side wiring 70 and a positive-side wiring 80. A connection node between the U-phase upper arm switch 21 and the U-phase lower arm switch 22 is connected to the U-phase coil 31 via the U-phase wiring 81.

The V-phase upper arm switch 23 and the V-phase lower arm switch 24 are connected in series between the negative-side wiring 70 and the positive-side wiring 80. A connection node between the V-phase upper arm switch 23 and the V-phase lower arm switch 24 is connected to the V-phase coil 32 via the V-phase wiring 82.

The W-phase upper arm switch 25 and the W-phase lower arm switch 26 are connected in series between the negative-side wiring 70 and the positive-side wiring 80. A connection node between the W-phase upper arm switch 25 and the W-phase lower arm switch 26 is connected to the W-phase coil 33 via the W-phase wiring 83.

The negative-side wiring 70 and the positive-side wiring 80 can be electrically connected to the battery 200 via the relay 51. The negative-side wiring 70 is connected to the negative terminal of the battery 200 when the relay 51 is in the ON state (closed state). The positive-side wiring 80 is connected to the positive terminal of the battery 200 when the relay 51 is in the ON state. The negative-side wiring 70 and the positive-side wiring 80 are electrically disconnected from the battery 200 when the relay 51 is in the OFF state (open state). A capacitor 61 is provided between the negative-side wiring 70 and the positive-side wiring 80. Additionally, setting to the ON state may also be referred to as ON control or closing control, while setting to the OFF state may also be referred to as OFF control or opening control.

The neutral point of the motor device 30 is connected to a neutral-point wiring 84. The neutral-point wiring 84 is configured as a pair with the negative-side wiring 70. The negative-side wiring 70 and the neutral-point wiring 84 can be electrically connected to a charging power source 410 via the external connection relay 52. The negative-side wiring 70 is connected to the negative terminal of the charging power source 410 when the external connection relay 52 is in the ON state. The neutral-point wiring 84 is connected to the positive terminal of the charging power source 410 when the external connection relay 52 is in the ON state. The negative-side wiring 70 and the neutral-point wiring 84 are electrically disconnected from the charging power source 410 when the external connection relay 52 is in the OFF state. A capacitor 62 is provided between the negative-side wiring 70 and the neutral-point wiring 84. Additionally, a fuse that melts in the event of overcurrent may be provided between the negative-side wiring 70 and the neutral-point wiring 84.

As described above, the relay 51 electrically connects and disconnects the charging stand 400 and the battery 200. The relay 51 corresponds to a switching device that may also be referred to as an opening-and-closing device. Additionally, the external connection relay 52 serves as an electrical connection port to the charging stand 400. The external connection relay 52 corresponds to a connection terminal. The external connection relay 52 can also be referred to as an inlet. A neutral point relay 53 is provided in the neutral-point wiring 84.

Each of the switching elements 21 to 26 is controlled by the ECU 10. The ECU 10 controls each of the switching elements 21 to 26 differently in the driving mode and the charging mode.

In the driving mode, the inverter circuit 20 supplies power from the battery 200 to the motor device 30. The motor device 30 is driven by the inverter circuit 20 to generate rotational driving force. The driving force generated by the motor device 30 is transmitted, for example, to the drive wheels of the automobile.

On the other hand, in the charging mode, the inverter circuit 20 and the motor device 30 operate as a booster circuit. The inverter circuit 20 and the motor device 30 boost the voltage of the charging power source 410 and supply the boosted voltage to the battery 200. The inverter circuit 20 and the motor device 30 correspond to a transformer circuit, a power transformation circuit or a voltage transformation circuit. Hereinafter, the inverter circuit 20 and the motor device 30 will also be referred to as the transformer circuit. The voltage of the charging power source 410 is also referred to as a charging voltage.

The negative-side wiring 70, the positive-side wiring 80, and the neutral-point wiring 84 are wirings for electrically connecting the external connection relay 52 and the battery 200 via the transformer circuit. The negative-side wiring 70, positive-side wiring 80, and neutral-point wiring 84 correspond to current paths for voltage transformation. In addition, the positive-side wiring 80 and the neutral-point wiring 84 correspond to current paths for power conversion on the high-potential side. The negative-side wiring 70 corresponds to the current path for power conversion on the low-potential side.

Hereinafter, the negative-side wiring 70, positive-side wiring 80, and neutral-point wiring 84 are collectively referred to as power conversion wiring. In addition, the positive-side wiring 80 and the neutral-point wiring 84 are collectively referred to as high-potential wiring. The negative-side wiring 70, the positive-side wiring 80, the phase wirings 81 to 83, and the neutral-point wiring 84 are part of the group of wirings.

Furthermore, the power conversion system 100 can also charge the battery 200 in the charging mode without passing through the transformer circuit. In other words, the charging mode includes a boost mode, in which the charging voltage is stepped up by the transformer circuit and supplied to the battery 200, and a bypass mode, in which the charging voltage is supplied to the battery 200 without being stepped up. To that end, the power conversion system 100 is equipped with a bypass wiring 90. The bypass wiring 90 corresponds to a bypass current path.

The bypass wiring 90 is a current path that branches off from the high-potential wiring and bypasses the transformer circuit. The first branching node 85 and the second branching node 86 are connection nodes of the bypass wiring 90 to the high-potential wiring. The first branching node 85 is provided on the neutral-point wiring 84. The second branching node 86 is provided on the positive-side wiring 80.

A bypass relay 91 is provided on the bypass wiring 90. Therefore, the bypass wiring 90 is configured to be capable of electrically connecting and disconnecting the external connection relay 52 and the battery 200. The bypass relay 91 is controlled to be in an OFF state during the boost mode and in an ON state during the bypass mode.

In the present embodiment, as an example, a configuration is adopted in which branching nodes 85 and 86 are provided on the high-potential wiring. Therefore, the high-potential wiring corresponds to a first current path. On the other hand, the negative-side wiring 70 corresponds to a second current path.

In addition, in the present embodiment, as an example, the bypass wiring 90 branched from the high-potential wiring is adopted. However, the present disclosure is not limited this example. The bypass wiring 90 may also be adopted as one that branches from the negative-side wiring 70. In this case, the high-potential wiring corresponds to a second current path, and the negative-side wiring 70 corresponds to a first current path.

The sensor device 40 is provided on the high-potential wiring and the negative-side wiring 70. The sensor device 40 outputs a sensor signal corresponding to the current flowing through the high-potential wiring and the negative-side wiring 70. The sensor device 40 outputs a sensor signal corresponding to the first current flowing between the first branching node 85 in the neutral-point wiring 84 and the transformer circuit, and the second current flowing through the negative-side wiring 70. The first branching node 85 is the branching node on the external connection relay 52 side in the neutral-point wiring 84. The first current can also be referred to as a neutral point current. The second current can also be referred to as an N current.

The sensor device 40 is provided to detect events such as leakage current in the power converter. Furthermore, the sensor device 40 is provided to detect whether an abnormality has occurred in the transformer wiring or the bypass wiring 90. In other words, the sensor device 40 can also be used for detecting whether an abnormality has occurred in the transformer wiring or the bypass wiring 90.

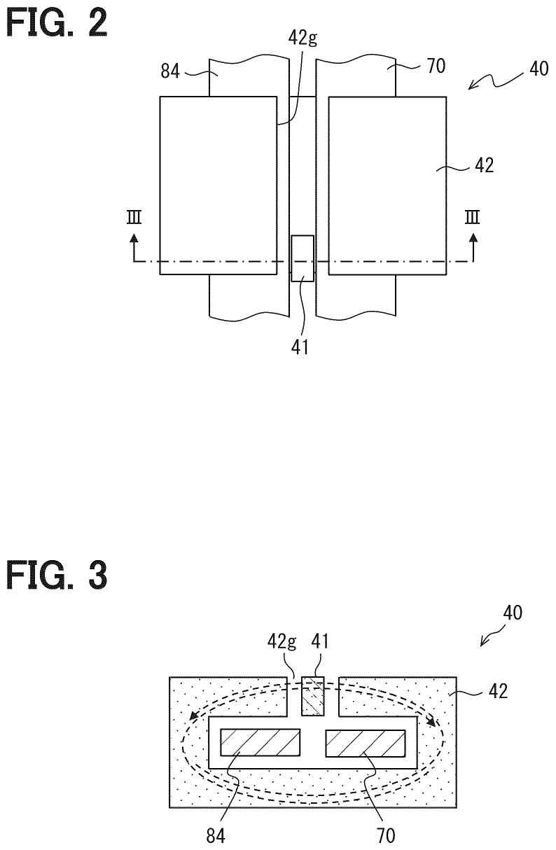

Here, a detailed explanation of the sensor device 40 will be given with reference to FIGS. 2 and 3. As shown in FIGS. 2 and 3, the sensor device 40 includes a Hall IC 41 and a core 42. The Hall IC 41 and the core 42 may be integrally sealed with an electrically insulating resin member. The sensor device 40 may also include a wiring board electrically connected to the Hall IC 41. The Hall IC 41 is electrically connected to the ECU 10.

The core 42 is provided so as to integrally surround both the neutral-point wiring 84 and the negative-side wiring 70. The core 42 serves to collect magnetic flux generated by the current flowing through the neutral-point wiring 84 and the negative-side wiring 70. The core 42 corresponds to a magnetic collection portion. The core 42 may also be referred to as a magnetic core or a magnetic material core. The core 42 is provided with a gap 42g. The gap 42g corresponds to a gap portion.

The Hall IC 41 outputs an electrical signal (sensor signal) corresponding to the magnetic state. The sensor device 40 outputs a sensor signal corresponding to the magnetic flux generated by the first current and the magnetic flux generated by the second current. Here, the magnetic state refers to a magnetic flux density. Also, the sensor signal here refers to a Hall voltage.

The Hall IC 41 includes a Hall element and a processing circuit that processes the signal output from the Hall element. The processing circuit includes an amplifier circuit for amplifying the signal, among other components. The Hall IC 41 is disposed in the gap 42g. In other words, the Hall IC 41 outputs a sensor signal corresponding to the magnetic state of the gap 42g. The Hall IC 41 corresponds to a magnetic detection element.

In the present embodiment, a Hall IC 41 is adopted as the magnetic detection element. However, the present disclosure is not limited to this, and a magnetic detection element equipped with a Magneto Resistance (MR) element or a Tunneling Magneto Resistance (TMR) element may also be adopted.

Here, using FIG. 1, the current in the power conversion system 100 during charging in the boost mode will be explained. The bypass relay 91 is in the OFF state during the boost mode. However, in FIG. 1, for convenience, the bypass relay 91 is illustrated in the ON state.

In a normal operation, current flows through the power conversion system 100 as indicated by the solid arrow. Therefore, the respective directions of current flow in the neutral-point wiring 84 and the negative-side wiring 70 are opposite to each other. In other words, the first current and the second current flow in opposite directions. The first current flows from the charging stand 400 side toward the battery 200 side. On the other hand, the second current flows from the battery 200 side toward the charging stand 400 side. The first current and the second current have the same current value.

Therefore, as shown in FIG. 3, the magnetic flux generated by the current flowing through the neutral-point wiring 84 and the magnetic flux generated by the current flowing through the negative-side wiring 70 cancel each other out. In other words, the magnetic flux to the Hall IC 41 is canceled out. Therefore, the Hall IC 41 does not output a sensor signal. Alternatively, the Hall IC 41 outputs an electrical signal at a level that can be regarded as a magnetic flux density of zero. It can also be said that the Hall IC 41 outputs a sensor signal indicating that the direction of the first current and the direction of the second current are opposite.

In the power conversion system 100, if the bypass relay 91 is erroneously turned on due to sticking or other causes, current flows as indicated by a dash-dot line arrow. Additionally, in the power conversion system 100, if a ground fault occurs due to leakage current via the chassis 300 or the like, current flows as indicated by a dash-double-dot line arrow. In other words, if the wiring for voltage transformation comes into contact with ground, current flows as indicated by the dash-double-dot line arrow. As described above, when an abnormality occurs in the wiring for voltage transformation or in the bypass wiring 90, the relationship between the direction of the first current and the direction of the second current differs from that under normal conditions.

Therefore, when an abnormality occurs in the bypass current path, the Hall IC 41 outputs a sensor signal indicating that the first and second currents are flowing in the same direction, or a sensor signal indicating that only one of the first or second current is flowing. In this embodiment, only the second current will flow. On the other hand, when an abnormality occurs in the current path for voltage transformation, the Hall IC 41 outputs a sensor signal indicating that the first and second currents are flowing in the same direction. As described above, the Hall IC 41 outputs a sensor signal only when an abnormality occurs in the wiring for voltage transformation or in the bypass wiring 90.

In addition, it can be said that when an abnormality occurs in the wiring for voltage transformation or in the bypass wiring 90, a difference arises between the first current and the second current. Therefore, the Hall IC 41 outputs a sensor signal only when a difference arises between the first current and the second current.

### Processing Operation

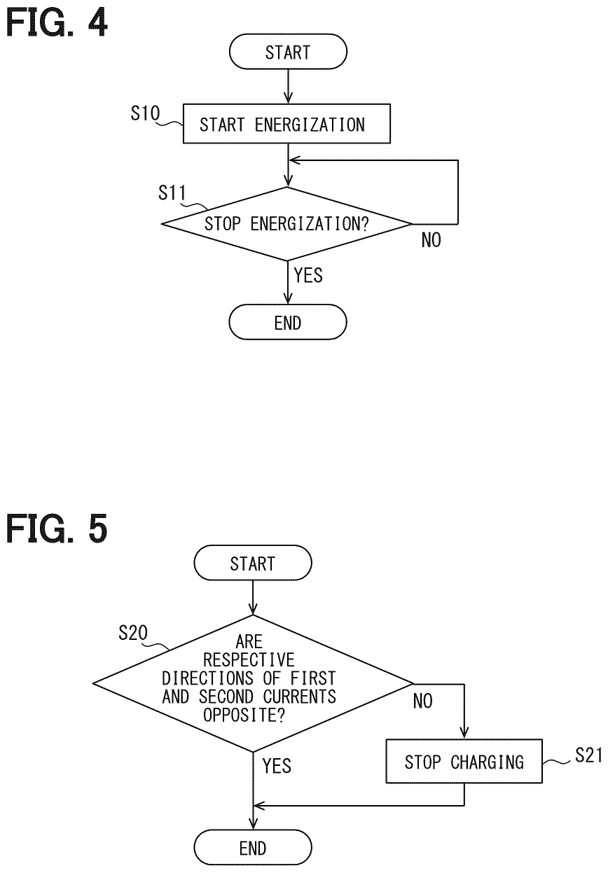

The processing operation of the ECU 10 will be explained with reference to FIG. 4 and FIG. 5. The ECU 10 starts the flowchart shown in FIG. 4 at the timing when charging of the battery 200 begins. The ECU 10 determines the timing for starting charging when the ECU 10 receives a charging start instruction signal from the charging stand 400. Additionally, the ECU 10 may also determine the timing for starting charging when the ECU 10 detects that the external connection relay 52 and the charging stand 400 have been connected.

In S10, power supply is started. S10 corresponds to energization or power supply. The ECU 10 controls each of the switching elements 21 to 26 in order to operate the inverter circuit 20 and the motor device 30 as a booster circuit. In addition, the ECU 10 controls relays 51 and 53 to the ON state, and controls the bypass relay 91 to the OFF state. In this manner, the ECU 10 executes the power conversion operation of the transformer circuit. As a result, the battery 200 is charged by the boosted charging voltage.

In S11, it is determined whether or not power supply is stopped. The ECU 10 determines that power supply is stopped, for example, when the ECU 10 receives a charging stop instruction signal from the charging stand 400, or when the connection between the external connection relay 52 and the charging stand 400 is disconnected. When the ECU 10 determines that power supply is stopped, the ECU 10 terminates the flowchart shown in FIG. 4. On the other hand, if the ECU 10 does not determine that power supply is stopped, the ECU 10 repeatedly executes S11. In other words, the ECU 10 continues to perform the voltage transformation operation until it determines that power supply is stopped.

While executing the voltage transformation operation, the ECU 10 starts the flowchart shown in FIG. 5. For example, the ECU 10 starts the flowchart shown in FIG. 5 at predetermined intervals. Additionally, the ECU 10 may start the flowchart shown in FIG. 5 via an interrupt when an event occurs.

In S20, it is determined whether the directions of the first current and the second current are opposite to each other. S20 corresponds to a determination. The ECU 10 checks the directions of the first current and the second current indicated by the sensor signals. That is, the ECU 10 determines whether an abnormality has occurred in the transformer wiring or the bypass wiring 90 based on the sensor signals from the sensor device 40.

If no sensor signal is output, the ECU 10 determines that the directions of the first current and the second current indicated by the sensor signal are opposite. Then, if the ECU 10 determines that the directions of the first current and the second current are opposite, the ECU 10 ends the flowchart in FIG. 5 without determining that an abnormality has occurred. It can also be said that, when no sensor signal is output, the ECU 10 determines that the transformer wiring or the bypass wiring 90 is normal.

On the other hand, when a sensor signal is output, the ECU 10 determines that the directions of the first current and the second current indicated by the sensor signal are the same. Then, if the ECU 10 determines that the directions of the first current and the second current are the same, the ECU 10 determines that an abnormality has occurred and proceeds to S21. It should be noted that, when a sensor signal is output, the ECU 10 may determine that only one of the first current and the second current is flowing, and determine that an abnormality has occurred. Additionally, it can also be said that, when a sensor signal is output, the ECU 10 determines that an abnormality has occurred in either the transformer wiring or the bypass wiring 90.

In S21, charging is stopped. The ECU 10 stops charging the battery 200. For example, the ECU 10 controls the relay 53 to an OFF state. When the relay 53 is turned to the OFF state, the charging stand 400 and the battery 200 are electrically disconnected. In this case, the ECU 10 can stop charging within the power conversion system 100.

The ECU 10 also outputs a stop request signal indicating stop of charging to the charging stand 400. The charging stand 400 stops supplying power in response to the stop request signal. In this case, the charging stand 400 can stop the supply of power itself to the power conversion system 100.

### Advantageous Effects

In the power converter as described above, the first current and the second current will differ depending on whether the transformer wiring and the bypass wiring 90 are normal, or whether an abnormality has occurred in the transformer wiring or the bypass wiring 90. Therefore, the sensor signal from the sensor device 40 differs between the normal state and the abnormal state. Accordingly, the power converter can detect the occurrence of an abnormality in either the transformer wiring or the bypass wiring 90.

Furthermore, it can be said that the power converter is configured such that the sensor device 40 detects an abnormality in the transformer wiring or the bypass wiring 90 based on the first current and the second current. Furthermore, it can also be said that the power converter is configured such that the sensor device 40 outputs an abnormality detection signal for detecting an abnormality in the transformer wiring or the bypass wiring 90 in accordance with the first current and the second current.

Additionally, in the power conversion system, as described above, the first current and the second current differ between the normal state and the state in which an abnormality has occurred. Therefore, during the execution of the voltage transformation operation, the ECU 10 determines the directions of the first current and the second current indicated by the sensor signal. Accordingly, the ECU 10 can detect, based on the sensor signal, whether an abnormality has occurred in the transformer wiring or the bypass wiring 90. In this manner, the power conversion system can detect an abnormality in the current paths.

The present embodiment describes an example in which the inverter circuit 20 and the motor device 30 are used as a voltage transformation circuit. However, the present disclosure is not limited this example. The power converter may include a voltage transformation circuit having a switching element that is not part of the inverter circuit 20 and a coil that is not part of the motor device 30. In other words, the power converter may also include a voltage transformation circuit having only one coil and only one switching element.

### Modified Example 1

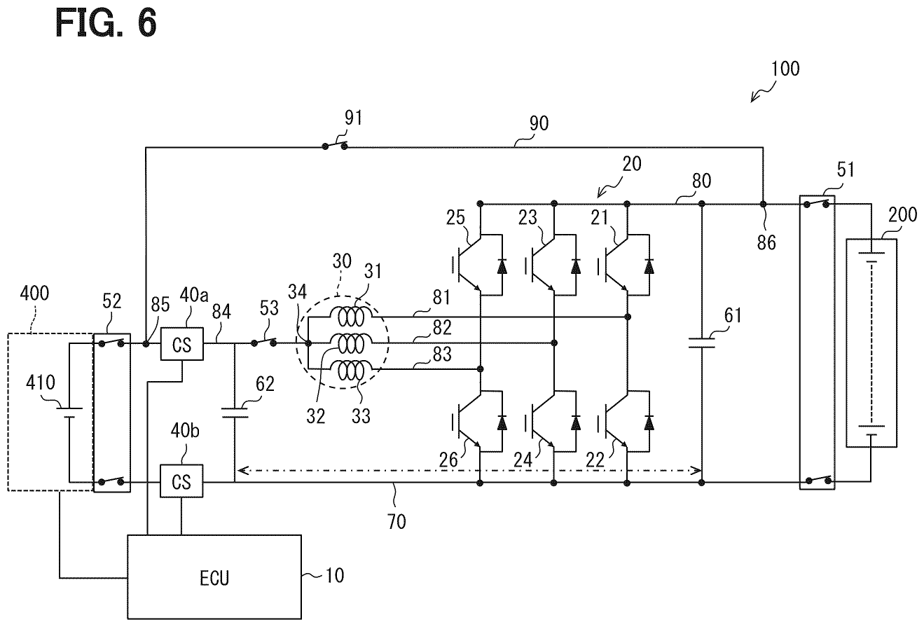

As shown in FIG. 6, the power converter according to a modified example may include a first sensor 40a and a second sensor 40b. The first sensor 40a is provided between a first branching node 85 in the neutral-point wiring 84 and the voltage transformation circuit. The second sensor 40b is provided on the negative-side wiring 70.

The first sensor 40a and the second sensor 40b, like the sensor device 40, include a Hall IC and a core. The core of the first sensor 40a is provided so as to surround only the neutral-point wiring 84 among the group of wirings. The core of the second sensor 40b is provided so as to surround only the negative-side wiring 70 among the group of wirings.

The first sensor 40a outputs a first signal corresponding to the first current as a sensor signal. The second sensor 40b outputs a second signal corresponding to the second current as a sensor signal. Therefore, the first sensor 40a and the second sensor 40b output the first signal and the second signal even when both the transformer wiring and the bypass wiring 90 are normal. In other words, when both the transformer wiring and the bypass wiring 90 are normal, the first signal and the second signal are signals indicating that the directions of the first current and the second current are opposite to each other.

On the other hand, when either the transformer wiring or the bypass wiring 90 is abnormal, the first signal and the second signal are signals indicating that the directions of the first current and the second current are the same. Alternatively, the first signal and the second signal are signals indicating that only one of the first current or the second current is flowing.

Then, based on the first signal and the second signal, the ECU 10 determines whether the directions of the first current and the second current are opposite to each other in S20. Therefore, the power converter according to the modified example can achieve the same effects as those of the above embodiment. The same applies to the power conversion system including the power converter according to the modified example.

Furthermore, the power conversion system 100 may be electrically connected to an external device such as a house instead of the charging stand 400. In this case, the external connection relay 52 is connected to a household outlet. Then, the power conversion system 100 is electrically connected to a device such as a storage battery or a distribution board installed in the house.

In a state where the power conversion system 100 is electrically connected to the house, the power conversion system 100 supplies (feeds) electric power from the battery 200 to devices such as the storage battery in the house. In other words, the power conversion system 100 operates in the power supply mode.

The inverter circuit 20 and the motor device 30 function as a step-down circuit in the power supply mode. The inverter circuit 20 and the motor device 30 step down the voltage of the battery 200 and supply the voltage to a device such as the storage battery.

In this case, the ECU 10 controls each of the switching elements 21 to 26 in S10 in order to operate the inverter circuit 20 and the motor device 30 as a step-down circuit (transformer circuit). In addition, the ECU 10 controls the relays 51 and 53 to the ON state, and controls the bypass relay 91 to the OFF state. In this manner, the ECU 10 executes the power conversion operation of the transformer circuit. As a result, the stepped-down voltage of the battery 200 is supplied to a device such as the storage battery. Even in the power supply mode, power may be supplied without step-down via the bypass wiring 90.

The embodiments of the present disclosure have been described above. However, although the present disclosure has been described in accordance with the embodiments, it is understood that the present disclosure is not limited to these embodiments or structures. The present disclosure also encompasses various modifications and equivalents within its scope. In addition, although various combinations and embodiments are disclosed herein, other combinations or embodiments that include only one element, more elements, or fewer elements are also within the scope and spirit of the present disclosure.

What is claimed is:

1. A power converter configured to be connected to an external device and a power supply, the power converter comprising:
a transformer circuit;
a connection terminal being an electrical port configured to be connected to the external device;
two transformer current paths respectively located at a high-potential side and a low-potential side of the power converter, the two transformer current paths electrically connected to the connection terminal and the power supply via the transformer circuit;
a bypass current path being a current path that branches from one of the two transformer current paths and bypasses the transformer circuit, the bypass current path configured to selectively establish and interrupt an electrical connection between the connection terminal and the power supply; and
a sensor device located at a first current path and a second current path, the first current path being the one of the two transformer current paths and having a branching node to which the bypass current path is connected, the branching node located between the connection terminal and the transformer circuit, the second current path being another of the two transformer current paths, the second current path not having the branching node,
wherein the sensor device is configured to output an electrical signal that varies according to a first current and a second current, the first current flowing between the branching node of the first current path and the transformer circuit, the second current flowing through the second current path.

2. The power converter according to claim 1,
wherein, upon occurrence of an abnormality in either the transformer circuit or the bypass current path, the sensor device is configured to output the electrical signal indicating that either: (i) respective directions of the first current and the second current are identical; or (ii) only one of the first current and the second current is flowing.

3. The power converter according to claim 2, wherein
the sensor device includes:
a magnetic collection portion integrally enclosing the first current path and the second current path and collecting a magnetic flux generated by respective currents flowing through the first current path and the second current path, the magnetic collection portion having a gap portion; and
a magnetic detection element located at the gap portion, the magnetic detection element configured to output the electrical signal according to a magnetic state of the gap portion, and
the magnetic detection element is configured to output the electrical signal only upon the occurrence of the abnormality in either the transformer circuit or the bypass current path.

4. The power converter according to claim 2, wherein
the sensor device includes:
a first sensor located between the branching node and the transformer circuit; and
a second sensor located at the second current path,
the electrical signal is one of electrical signals including a first signal and a second signal,
the first sensor is configured to output the first signal that varies according to the first current, and
the second sensor is configured to output the second signal that varies according to the second current.

5. The power converter according to claim 1, further comprising:
a controller configured to determine whether an abnormality occurs in either the transformer current path or the bypass current path, based on the electrical signal from the sensor device.

6. A power conversion system configured to be connected to an external device and a power supply, the power conversion system comprising:
a transformer circuit;
a controller configured to control the transformer circuit;
a connection terminal being an electrical port configured to be connected to the external device;
two transformer current paths respectively located at a high-potential side and a low-potential side of the power conversion system, the two transformer current paths electrically connected to the connection terminal and the power supply via the transformer circuit;
a bypass current path being a current path that branches from one of the two transformer current paths and bypasses the transformer circuit, the bypass current path configured to selectively establish and interrupt an electrical connection between the connection terminal and the power supply; and
a sensor device located at a first current path and a second current path, the first current path being the one of the two transformer current paths and having a branching node to which the bypass current path is connected, the branching node located between the connection terminal and the transformer circuit, the second current path being another of the two transformer current paths, the second current path not having the branching node, wherein
the sensor device is configured to output an electrical signal that varies according to a first current and a second current, the first current flowing between the branching node of the first current path and the transformer circuit, the second current flowing through the second current path, and
the controller is configured to:
execute a voltage transformation operation of the transformer circuit; and
determine, during execution of the voltage transformation operation, respective directions of the first current and the second current that are indicated by the electrical signal.

7. The power conversion system according to claim 6, further comprising:
a switching device configured to selectively establish and interrupt an electrical connection between the external device and the power supply, wherein
the controller is configured to interrupt the electrical connection between the external device and the power supply by turning the switching device to an open state, on condition that the controller determines that an abnormality occurs.

8. The power conversion system according to claim 6, wherein
the external device is a charging device configured to charge the power supply,
the controller is configured to output a stop request signal to the external device, on condition that the controller determines that an abnormality occurs, and
the stop request signal indicates a request to stop charging the power supply.
